(19) United States
(12) Patent Application Publication
(10) Pub. No.: US 2026/0248023 A1
(43) Pub. Date: Aug. 20, 2026

(54) SEMICONDUCTOR DIE-STACK HAVING SEALED EDGES

(71) Applicant: SEMICONDUCTOR COMPONENTS INDUSTRIES, LLC, Scottsdale, AZ (US)

(72) Inventors: Ying-Hung CHENG, New Taipei City (TW); Yi Yi CHAN, Hsinchu City (TW); Liang Yu CHIU, New Taipei City (TW)

(73) Assignee: SEMICONDUCTOR COMPONENTS INDUSTRIES, LLC, Scottsdale, AZ (US)

(21) Appl. No.: 19/057,891

(22) Filed: Feb. 19, 2025

(51) Int. Cl. H01L 21/56; H01L 21/78; H01L 23/00; H01L 25/16; H10F 39/00; H10F 39/95

(52) U.S. Cl. CPC H10W 74/014; H10F 39/014; H10P 54/00; H10F 39/95; H10W 80/312; H10W 80/327; H10W 80/334; H10W 90/00

(57) ABSTRACT

Three-dimensional integration of devices, such as image sensors, may result in die-to-die delamination. The present disclosure describes a method to enhance die-to-die bonding and prevent moisture absorption. The method includes adding a sealing material to the side walls of a die-stack in order to strengthen a seam between the die layers and to block moisture absorption. The sealing material may also be used on a top surface of an image sensor to support and adhere to a glass window.

### FIELD OF THE DISCLOSURE

The present disclosure relates to semiconductor packaging and more specifically to a semiconductor package in which multiple wafers are bonded together in layers.

### BACKGROUND

A semiconductor package (i.e., package) may include a vertical stack of semiconductor dies (i.e., chips) that are mechanically and electrically coupled to form a system. This packaging approach may be referred to as three-dimensional (3D) integration. Image sensors may utilize 3D integration to reduce complexity and size. A package for an image sensor, such as a CMOS image sensor (i.e., CIS), may include a stack having a sensor layer (i.e., sensor-die) and an application specific integrated circuit (i.e., ASIC) layer (i.e. ASIC-die). The sensor-die can include a two-dimensional array of photosensitive diodes (i.e. pixels), which can be addressed by rows and columns via switches and traces. The ASIC-die can convert the signals received from the pixels into digital levels. The digital levels may be collected in frames, in which the pixels combine to form a gray scale image. Color filters may configure the pixels to collect light in different color channels so that a frame from each color channel can be collected and combined to form a color image. A bad connection between the sensor-die and the ASIC-die can lead to problems with this image generation.

### SUMMARY

An image sensor is disclosed that includes features to preserve a good connection between the sensor-die and the ASIC die over time, and even in harsh environments.

In some aspects, the techniques described herein relate to a method including: creating a wafer-stack by bonding a bottom surface of a top wafer to a bottom wafer; cutting a groove in a top surface of the top wafer along a boundary that surrounds an active area of the top wafer, the groove having a depth that is greater than a thickness of the top wafer; depositing a sealing material into the groove; and creating a die-stack by sawing through the sealing material and the bottom wafer in the groove so that a portion of the sealing material is left deposited on edges of the die-stack covering a seam between a top die and a bottom die.

In some aspects, the techniques described herein relate to a method for fabricating an image sensor, the method including: bonding an image-sensor wafer to an integrated-circuit wafer to create a wafer-stack; laser-cutting a groove into a top surface of the image-sensor wafer, the groove exposing a seam between the image-sensor wafer and the integrated-circuit wafer; dispensing a sealing material into the groove to cover the seam; and dicing the wafer-stack to create a sensor die-stack that includes the sealing material covering the seam.

In some aspects, the techniques described herein relate to a method for fabricating image sensors, the method including: bonding an image-sensor wafer to an integrated-circuit wafer; cutting grooves in a top surface of the image-sensor wafer, the grooves surrounding active areas of the image-sensor wafer and the grooves exposing a seam between the image-sensor wafer and the integrated-circuit wafer; depositing a sealing material into the grooves; and sawing through the sealing material and the integrated-circuit wafer in the grooves to create a plurality of sensor die-stacks, each sensor die-stack having a respective seam covered by the sealing material.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 is a side, cross-sectional view of an image sensor according to a possible implementation of the present disclosure.

FIG. 2A is a top-surface of a wafer-stack according to a possible implementation of the present disclosure.

FIG. 2B is a side-view of the wafer-stack shown in FIG. 2A.

FIG. 2C is a side-view of a die-stack diced from the wafer-stack shown in FIG. 2B.

FIG. 3A is a side-view of an edge of a die-stack with no delamination according to a possible implementation of the present disclosure.

FIG. 3B is a side-view of the edge of the die-stack with delamination according to a possible implementation of the present disclosure.

FIG. 3C is a side-view of the edge of the die-stack with sealing material according to a possible implementation of the present disclosure.

FIG. 4 is a flowchart of a method for fabricating a semiconductor die-stack having sealed edges according to a possible implementation of the present disclosure.

FIG. 5A illustrates grooves cut in a top surface of a wafer-stack according to a possible implementation of the present disclosure.

FIG. 5B is a side-view of the grooves shown in FIG. 5A.

FIG. 6A is a side-view illustrating a wafer-stack with sealing material according to a first possible implementation of the present disclosure.

FIG. 6B is a side-view illustrating a die-stack separated from the wafer-stack of FIG. 6A.

FIG. 7A is a side-view illustrating a wafer-stack with sealing material according to a second possible implementation of the present disclosure.

FIG. 7B is a side-view illustrating the wafer-stack with the sealing material of FIG. 7A after etching according to a possible implementation of the present disclosure.

FIG. 7C is a side-view illustrating a die-stacks separated from the wafer-stack of FIG. 7B.

FIG. 8 is a side-view of an image-sensor according to a possible implementation of the present disclosure.

The components in the drawings are not necessarily to scale relative to each other. Like reference numerals designate corresponding parts throughout the several views.

### DETAILED DESCRIPTION

Two semiconductor wafers can be bonded together to form a stack of wafers (i.e., wafer-stack) with two layers. The wafer-stack can then be cut (i.e., diced) to form multiple die-stacks, each having two die layers. For reference, the term “die” used herein refers to a portion of a wafer that includes an integrated circuit. Multiple dies may be created by dicing a wafer. For example, a wafer may include multiple replicas of an integrated circuit, and the dicing may create multiple duplicate dies. A die-stack may be created by dicing after aligning and bonding the respective dies of the wafers.

The dicing may include laser grooving to partially divide the die-stacks and then sawing along the grooves to completely separate the die-stacks. A technical problem with this approach is that the laser grooving can create a recast material along the edges of each die stack, which covers the seam between the die layers. The recast material can absorb moisture, which can increase its coefficient of thermal expansion. As a result, thermal cycling can cause the recast material, filled with moisture, to generate a stress that acts to separate the die layers. Over time, the thermal cycling and moisture absorption can create a separation (i.e., delamination), which can electrically disconnect the die layers, causing the device to malfunction.

A technical solution is disclosed that includes a method for fabrication in which a sealing material is used to seal and protect the recast material so that it absorbs less moisture (e.g., no moisture). The sealing material may reduce (e.g., eliminate) an amount of moisture absorbed by the recast material to help prevent the separation of the die layers. The disclosed methods may have the technical effect of improving the operation of a device (e.g., image sensor) over time.

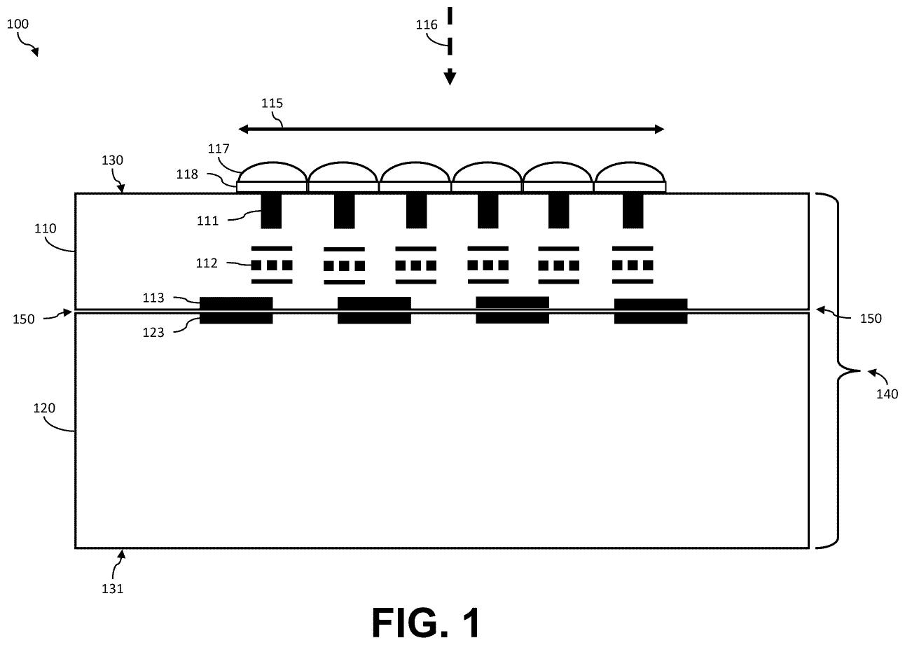

FIG. 1 is a side, cross-sectional view of an image sensor according to a possible implementation of the present disclosure. The image sensor 100 includes sensing circuitry and the processing circuitry implemented on separate substrates (i.e., dies). Image sensors in this configuration may be referred to as stacked because they include a stack of circuit layers that function collectively as the device (i.e., image sensor). While two dies are used as an example to simplify the discussion, the disclosed methods may be applied to die-stacks with more than two layers. For example, an image sensor may include an interconnection layer between a sensor layer and a circuit layer. In this case, a sealing material could be used to cover (i.e., seal) two seams instead of one. Additional layers for the image sensor, or another 3D integrated device, may be conceived. Accordingly, the disclosed methods may be applied to stacked configurations (i.e., 3D integrations) including any number of layers.

As shown in FIG. 1, the image sensor 100 (e.g., CMOS image sensor) may include an image-sensor die (i.e., sensing layer) having an array of photodiodes 111. An area of a two-dimensional array of photodiodes 111 (i.e., pixels) may be referred to as the active area 115 of the image-sensor die 110.

The active area 115 may be on a surface facing light 116 received by the image sensor 100. This surface may be referred to as the top surface 130 of the image sensor 100. A surface at an opposite side of the image sensor 100 may be referred to as the bottom surface 131 of the image sensor 100. The top surface 130 and the bottom surface 131 may serve as references for describing the position of elements in the disclosure. Elements may be referred to as above or below based on their relative proximity to the top surface 130 and the bottom surface 131, respectively. For example, a first element that is closer to the top surface 130 than a second element may be referred to as being above the second element. Each layer may have a top surface and a bottom surface, with the top layer being at, or closer to, the top surface 130 than the bottom surface of the layer. A direction normal to the top surface may be referred to as vertical while a direction orthogonal to the top surface may be referred to as horizontal. The figures are arranged to conform with these conventions.

As shown in FIG. 1, The image sensor 100 may include a sensor die-stack 140 that includes an image-sensor die 110 and an integrated-circuit die 120 arranged vertically so that a bottom surface of the image-sensor die 110 and a top surface of the integrated-circuit die 120 form a seam 150. As shown in FIG. 1, the seam 150 may be exposed at the (vertical) edges of the image sensor 100.

The image-sensor die 110 may include photodiodes 111 in an active area 115 (i.e., pixel area) of the top surface 130 of the sensor die-stack 140. The photodiodes 111 can be configured to convert the light 116 into electrical signals. In a possible implementation, the image-sensor die 110 may further include electrical traces and vias (i.e., metal stack 112) located below the plurality of photodiodes 111 to route the electrical signals to and from the plurality of photodiodes 111.

The image-sensor die 110 and the integrated-circuit die 120 can be configured to exchange electrical signals via sensor pads 113 and circuit pads 123, which can be electrically (and mechanically) coupled during a wafer bonding process (e.g., hybrid bonding). For example, heat and force applied a pad-to-pad (e.g., copper-to-copper interface) between the sensor pads 113 and the circuit pads 123 may help bond the image-sensor die 110 to the integrated-circuit die 120. The sensor pads 113 and the circuit pads 123 can be electrically disconnected if the image-sensor die 110 and the integrated-circuit die 120 are pulled apart (i.e., delaminated). This disconnection may cause the image sensor 100 to not operate or operate improperly.

In a possible implementation, the integrated-circuit die 120 is an application specific integrated circuit (ASIC) configured to address the plurality of photodiodes 111 and receive their respective light-detection levels. The ASIC may be further configured to convert light-detection levels into digital levels to form an image.

In a possible implementation, the image sensor 100 may further include an array of lenses (i.e. lenslet array 117) positioned on the top surface 130 of the image-sensor die 110 and aligned with the photodiodes 111 in the active area 115. The lenslet array 117 can be used to help gather and direct the light 116 to the plurality of photodiodes 111. Additionally, the active area 115 may further include color filters 118, which can be configured to separate the light 116 into color channels for the purpose of rendering a color image.

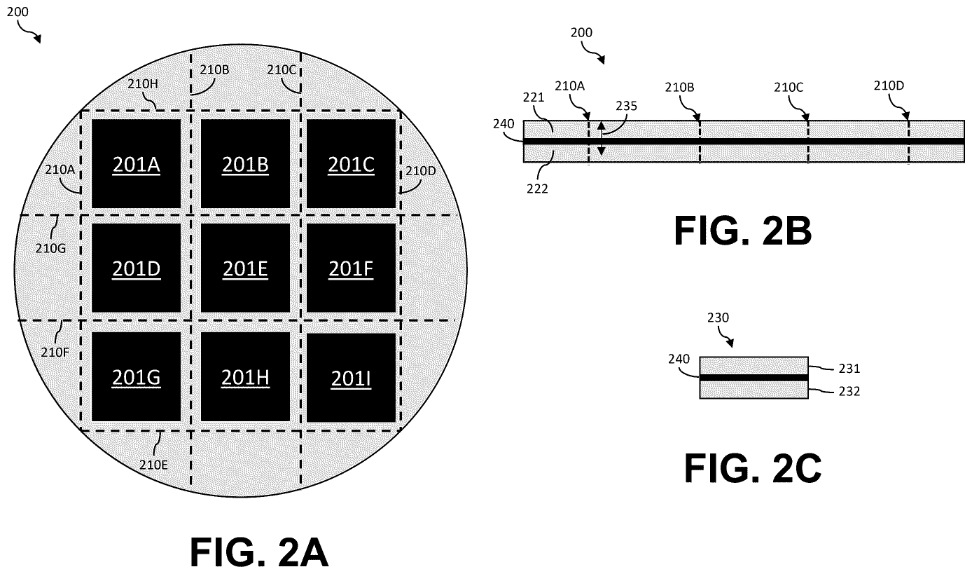

FIG. 2A is a top-surface of a wafer-stack and FIG. 2B is a side-view of the wafer-stack. The top wafer and the bottom wafer may be bonded together using a hybrid bonding process that includes applying a heat and/or a force to a polymer between a bottom surface of the top wafer and a top surface of the bottom wafer. The wafer-stack 200 can include a plurality of active areas 201A-I. The plurality of active areas may each be surrounded by boundaries 210A-H, along which a cutting instrument may be moved to separate (i.e., dice) the wafer-stack 200 into die-stacks. As shown in FIG. 2B, the top wafer 221 and the bottom wafer 222 define an interface (i.e., seam 240) between the layers.

Dicing may include cutting through the layers of the wafer-stack along the boundaries. The dicing may require one or more cuts to cut all boundaries (i.e., horizontally) and may require one or more cuts to cut through the layers (i.e. vertically). In a possible implementation, the dicing may include cutting a groove in the top surface of the top wafer 221. For example, a laser beam may be focused on and moved along the boundaries 210A-H to cut grooves in the wafer-stack 200. Each groove may have a depth 235 that penetrates through the top wafer 221 but does not completely penetrate the bottom wafer 222 so that the seam 240 is exposed by the groove. The laser grooving includes generating recast material along the depth 235 of the groove, which includes the seam 240. After the laser grooving, the die stacks remain attached. A wafer saw can then separate the die-stacks by sawing along the grooves. For example, the sawing may include positioning a cutting edge of a wafer saw within a groove so that it cuts through a bottom of the groove and then moving the saw along the groove to create a die-stack (or die-stacks) from a wafer-stack 200.

FIG. 2C is a side-view of a die-stack cut (i.e., diced) from the wafer-stack shown in FIG. 2B. As shown, a die-stack 230 can include a top die 231 and a bottom die 232. In a possible implementation, the die-stack 230 is a sensor die-stack, the top die 231 is an image-sensor die, and the bottom die 232 is an integrated-circuit die. The dicing (e.g., laser grooving plus wafer sawing) exposes the seam 240 between the top die 231 and the bottom die 232 at the edges (i.e., sides) of the die-stack 230.

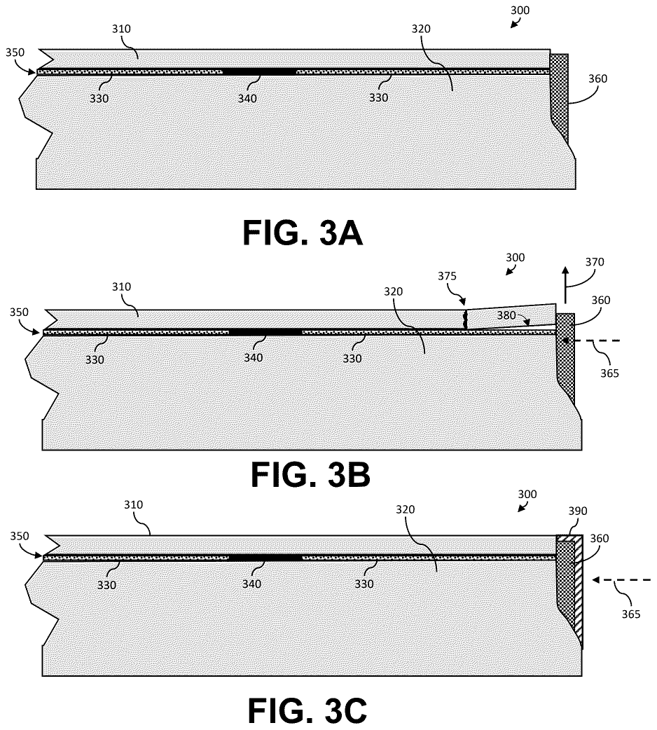

FIG. 3A is a side-view of an edge of a die-stack with no delamination according to a possible implementation of the present disclosure. As mentioned, a die-stack may be created by a dicing process that includes two operations. A first operation may be laser grooving to cut a groove (i.e., trench) into the top surface of a top wafer along a boundary that surrounds an active area of the top wafer. The heat of the laser grooving may melt the (vertical) edges of the die-stack. The molten material can then be re-solidified, forming a recast material (i.e., recast layer) on the (vertical edges) of the die-stack. The first operation (e.g., laser grooving) may be followed by a second operation to separate the die-stack by sawing the wafer-stack along the groove. For example, the remaining wafer stack not removed by the laser grooving may be cut (i.e. sawed) through at a bottom surface of the groove. The cutting (i.e., wafer sawing) may remove some, but not all, of the recast material.

As shown in FIG. 3A, a die-stack 300 (e.g., sensor die-stack) can include a top die 310 (e.g., image-sensor die) bonded to a bottom die 320 (e.g., ASIC die). The bond can be a hybrid bond that includes both adhesive bonds 330 and metal-to-metal bonds 340. The bond forms a seam 350 at the edges of the die stack created during the cutting process. Recast material 360 resulting from the cutting process can remain at the edges to cover the seam 350. In other words, the recast material may cover, at least, the seam 350 at the edge of the die-stack 300. As shown in FIG. 3A, the recast material can be adjacent to the bond (e.g., adhesive bond) between the top die 310 and the bottom die 320.

FIG. 3B is a side-view of the edge of the die-stack with delamination according to a possible implementation of the present disclosure. The recast material 360 may create a force 370, which can help to create a separation 380 at the seam 350. In other words, the force may help to delaminate the layers of the die stack. In some cases, the force 370 may help cause a crack 375 to form in the top die 310 of the die-stack 300.

The force 370 may result from moisture 365 absorbed by the recast material 360. The recast material 360 may be porous and so may absorb moisture (e.g., water) from the environment. For example, a vehicle can experience large ranges of humidity and temperature. An image sensor with recast material operated in such an environment may be prone to cracks and/or delamination over time. For example, the recast material may accumulate moisture. The moisture may have the effect of increasing the expansion of the recast material with temperature (i.e., coefficient of thermal expansion (CTE)). For example, moisture absorbed by the recast material 360 may freeze, thereby creating a stress that acts against the adhesive bond of the seam 350. Repeated thermal cycling can iteratively separate the layers until the structural integrity of the die-stack is damaged through a separation 380 or a crack 375 (e.g., partial crack). This damage may affect the electrical communication between the layers of the die-stack, which can ultimately disable the device or otherwise impair its operation. The damaged image sensor may require repair or replacement, which may be understood as undesirable for a variety of reasons.

FIG. 3C is a side-view of the edge of the die-stack with sealing material according to a possible implementation of the present disclosure. The sealing material 390 can be used to prevent (i.e., block) the moisture 365 from entering the recast material 360. The sealing material 390 may be deposited (e.g., dispensed) into the groove formed by the initial cut of the dicing process (i.e., the laser grooving). The second cut of the dicing process may saw through the sealing material, leaving a portion of the sealing material 390 deposited on the edges of the die-stack 300. The portion covers the recast material at the seam 350 between the top die 310 and the bottom die 320. The sealing material 390 may be a hydro-phobic material that can be dispensed and hardened to form a protective cover for the edges of the die-stack, especially in the area of the seam 350. The sealing material may also form a strengthener for the seam of the die-stack, which strengthens the bond between layers. In a possible implementation, the sealing material is a dry-film photoresist material. In another possible implementation, the sealing material is an epoxy.

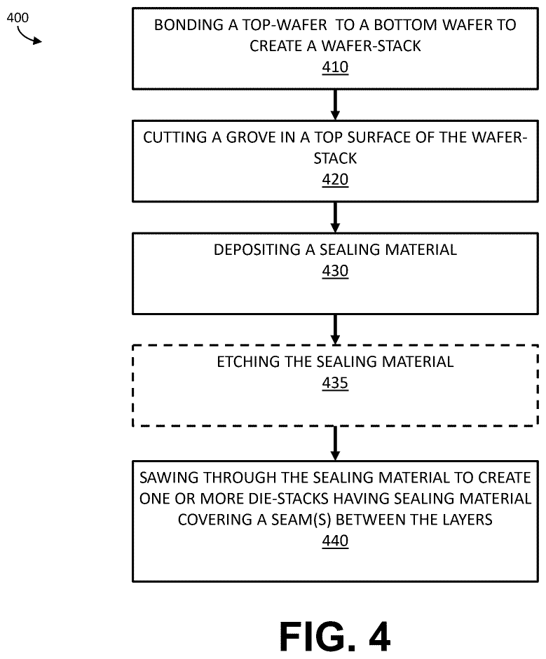

FIG. 4 is a flowchart of a method for fabricating a semiconductor die-stack having sealed edges according to a possible implementation of the present disclosure. The method 400 includes bonding 410 a top-wafer to a bottom wafer to create a wafer-stack. In a possible implementation, the bonding is a hybrid bonding process that includes applying a heat and a force to a polymer between the top-wafer and the bottom-wafer and applying the heat and the force to a metal-to-metal (e.g. copper-to-copper) interface between the top wafer and the bottom wafer.

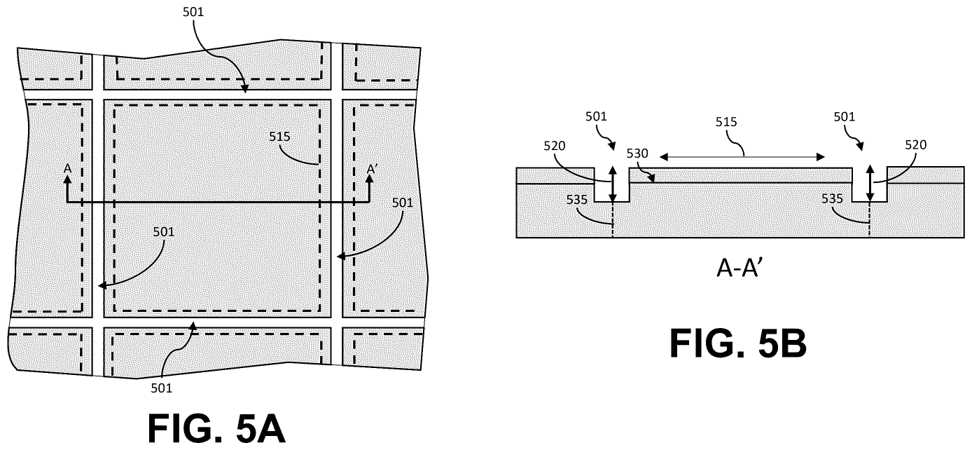

The method 400 further includes cutting 420 (e.g., laser-cutting) a groove (or grooves) into a top surface of the wafer-stack. FIG. 5A illustrates grooves cut in a top surface of a wafer-stack according to a possible implementation of the present disclosure. As shown, the top surface may have an active area 515 and the cutting may create a groove 501 along a boundary (i.e. perimeter) that surrounds the active area 515. In a possible implementation the cutting 420 includes focusing a laser beam, generated by a laser, onto the top surface of the wafer stack and moving the laser beam along the boundary to cut the groove 501 (i.e., trench) into the wafer-stack. Cutting the groove 501 may create a layer of recast material on the interior sides of the groove by melting and re-solidifying the wafer material (e.g., silicon) at the interior surfaces (i.e., sides) of the groove.

FIG. 5B is a side-view of the grooves shown in FIG. 5A. As shown, the grooves may be cut to a depth 520 that is greater than a first thickness of a top-wafer and is less than a second thickness of the entire wafer-stack. In other words, the groove 501 may be deep enough to expose a seam 530 between the top-wafer (e.g., image-sensor wafer) and the bottom-wafer (e.g., integrated-circuit wafer). Dicing the wafer stack may include sawing along a saw line 535.

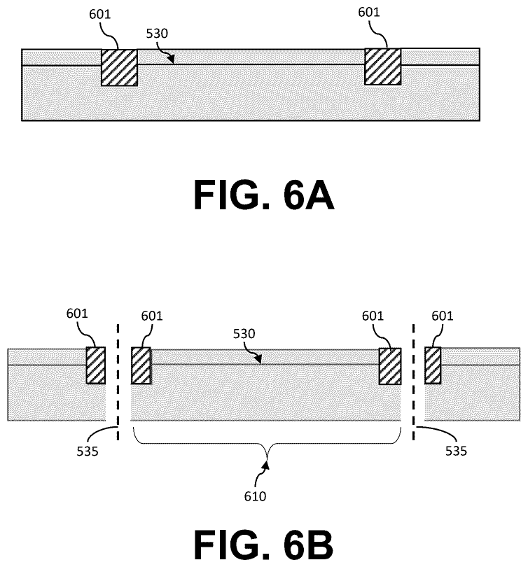

As shown in FIG. 4, the method 400 further includes depositing 430 a sealing material into the groove 501. FIG. 6A is a side-view illustrating a wafer-stack with sealing material according to a first possible implementation of the present disclosure. As shown, depositing the sealing material 601 may substantially fill the interior volume defined by the groove 501. For example, the sealing material 601 may fill the groove to at least to a level that covers the seam 530.

As shown in FIG. 4, the method 400 further includes sawing 440 through the sealing material 601 to create one or more die-stacks having sealing material covering the seam(s) between the layers. FIG. 6B is a side-view illustrating a die-stack 610 separated from the wafer-stack of FIG. 6A. The separating may include sawing through the sealing material 601 and the bottom wafer so that a die-stack is created. The sawing leaves sealing material deposited on the edges of the die-stack to cover (i.e., overlap) the seam 530 of the die-stack 610. In a possible implementation the sawing may include bisecting a bottom surface of the groove 501, as shown in the saw line 535 of FIG. 6B.

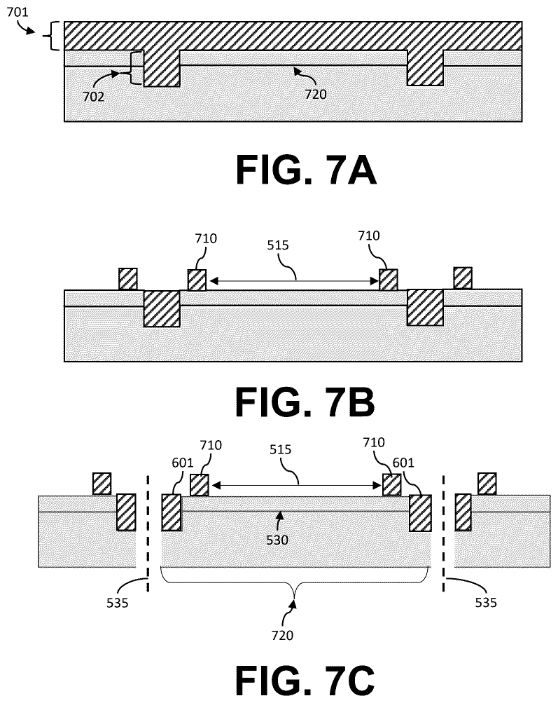

In a possible implementation of the method 400, shown in FIG. 4, the depositing 430 of the sealing material may include depositing a layer of the sealing material the wafer-stack. FIG. 7A is a side-view illustrating a wafer-stack with sealing material according to a second possible implementation of the present disclosure. As shown, a first portion 701 of the deposited sealing material is a layer on a top surface of the top wafer and a second portion 702 of the deposited sealing material fills the groove to cover the seam.

In a possible implementation, the method 400 may include etching 435 (e.g., photo-etching) the deposited sealing material. FIG. 7B is a side-view illustrating the wafer-stack with the sealing material after etching according to a possible implementation of the present disclosure. The sealing material may be etched so that the second portion of the sealing material 601 remains in the groove and the etching 435 may further create a glass support 710 on the top surface of the top-wafer. The glass support 710 may surround the active area 515 and may have a height and strength configured to support and position a glass window above an active area of an image-sensor die.

FIG. 7C is a side-view illustrating a die-stack separated from the wafer-stack of FIG. 7B. As before, the separating may include sawing through the sealing material and the bottom wafer so that a die-stack 720 is created. The sawing (e.g., along a saw line 535) leaves sealing material deposited on the edges of the die-stack to cover (i.e., overlap) the seam 530 of the die-stack 720.

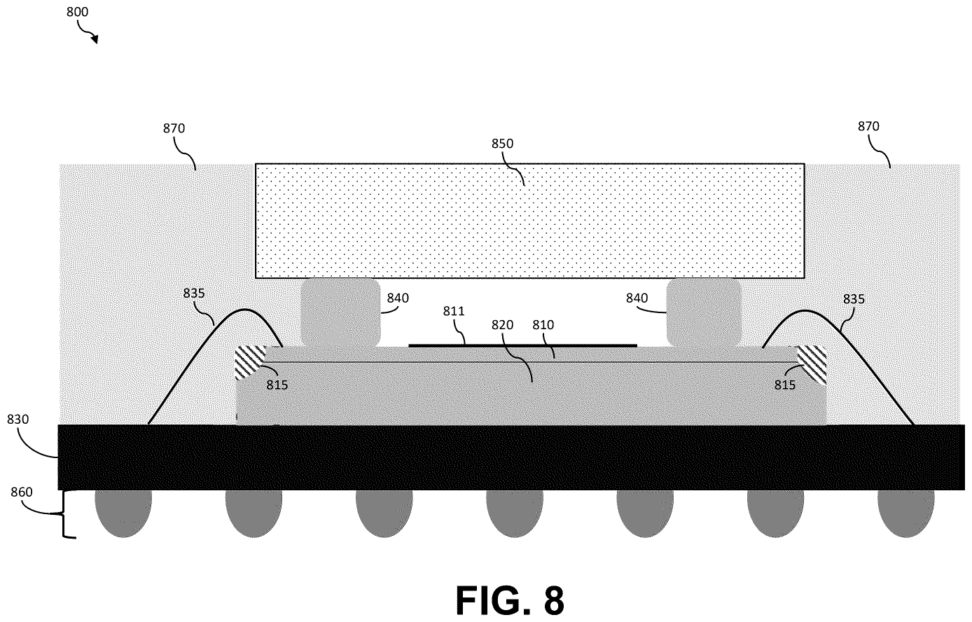

The die-stack with sealed edges may be assembled into an image sensor. FIG. 8 is a side-view of an image sensor 800 according to a possible implementation of the present disclosure. The image sensor 800 includes a sensor die-stack with sealing material 815 covering (i.e., sealing, protecting) a seam between an image-sensor die 810 (i.e., top die) and an integrated-circuit die 820 (i.e., bottom die). In a possible implementation, the image-sensor die 810 is a complementary metal-oxide semiconductor (CMOS) image sensor and the integrated-circuit die 820 is an application-specific integrated circuit (ASIC). The sensor die-stack can be adhered to a substrate 830 using a die adhesion layer. Wire-bonds may bond wires 835 between the image-sensor die 810 and the substrate 830. A glass window 850 may be coupled to a glass support 840 and provide protection of the sensor area 811 (i.e., active area) without blocking light from reaching the sensor area 811. The image sensor 800 may further include encapsulating material 870, which can be applied around the glass window 850, the glass support 840, the image-sensor die 810, and the integrated-circuit die 820 and which may cover a portion of the substrate 830. The image sensor 800 may further include interconnects 860 (e.g., pins, balls) on a bottom surface of the substrate 830 to provide electrical contact to other devices.

In the specification and/or figures, typical embodiments have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

1. A method comprising:
creating a wafer-stack by bonding a bottom surface of a top wafer to a bottom wafer;
cutting a groove in a top surface of the top wafer along a boundary that surrounds an active area of the top wafer, the groove having a depth that is greater than a thickness of the top wafer;
depositing a sealing material into the groove; and
creating a die-stack by sawing through the sealing material and the bottom wafer in the groove so that a portion of the sealing material is left deposited on edges of the die-stack covering a seam between a top die and a bottom die.

2. The method according to claim 1, wherein:
cutting the groove creates recast material at the seam between the top die and the bottom die; and
the sealing material covers the recast material at the seam between the top die and the bottom die.

3. The method according to claim 2, wherein the sealing material blocks water from entering the recast material.

4. The method according to claim 2, further comprising:
reducing a thermal expansion of the recast material by using the sealing material to block moisture from entering the recast material.

5. The method according to claim 1, wherein the top die is a complementary metal-oxide semiconductor (CMOS) image sensor, and the bottom die is an application-specific integrated circuit (ASIC).

6. The method according to claim 1, wherein bonding the bottom surface of the top wafer to the bottom wafer is a hybrid bonding process that includes:
applying a heat and a force to a polymer between the bottom surface of the top wafer and the bottom wafer; and
applying the heat and the force to a copper-to-copper interface between the bottom surface of the top wafer to the bottom wafer.

7. The method according to claim 1, wherein cutting the groove includes:
focusing a laser beam onto the top surface and moving the laser beam along the boundary to cut the groove in the top surface of the top wafer.

8. The method according to claim 1, wherein sawing through the sealing material and the bottom wafer includes the groove includes:
using a wafer saw to separate the die-stack from the wafer-stack.

9. The method according to claim 1, wherein depositing the sealing material into the groove further includes:
depositing a layer of the sealing material on the top surface of the top wafer.

10. The method according to claim 9, further comprising:
etching the layer to create a glass support on the top surface of the top wafer, the glass support positioned between the groove and the active area.

11. The method according to claim 1, wherein the sealing material is a dry-film photoresist material or an epoxy.

12. A method for fabricating an image sensor, the method comprising:
bonding an image-sensor wafer to an integrated-circuit wafer to create a wafer-stack;
laser-cutting a groove into a top surface of the image-sensor wafer, the groove exposing a seam between the image-sensor wafer and the integrated-circuit wafer;
dispensing a sealing material into the groove to cover the seam; and
dicing the wafer-stack to create a sensor die-stack that includes the sealing material covering the seam.

13. The method for fabricating the image sensor according to claim 12, wherein dispensing the sealing material into the groove to cover the seam includes:
dispensing a dry-film photoresist material on the top surface of the wafer-stack, the dry-film photoresist material filling the groove and covering the top surface; and
photo-etching the dry-film photoresist material so that a first portion of the dry-film photoresist material covers the seam in the groove, and a second portion of the dry-film photoresist material surrounds a sensor area of the image-sensor wafer.

14. The method for fabricating the image sensor according to claim 13, further comprising bonding a glass window to the second portion.

15. The method for fabricating the image sensor according to claim 12, further comprising:
adhering the sensor die-stack to a substrate;
bonding a wire between an image-sensor die of the sensor die-stack and the substrate;
depositing a glass support around an active area of the image-sensor die;
coupling a glass window to the glass support; and
applying encapsulating material around the glass window.

16. A method for fabricating image sensors, the method comprising:
bonding an image-sensor wafer to an integrated-circuit wafer;
cutting grooves in a top surface of the image-sensor wafer, the grooves surrounding active areas of the image-sensor wafer and the grooves exposing a seam between the image-sensor wafer and the integrated-circuit wafer;
depositing a sealing material into the grooves; and
sawing through the sealing material and the integrated-circuit wafer in the grooves to create a plurality of sensor die-stacks, each sensor die-stack having a respective seam covered by the sealing material.

17. The method for fabricating the image sensors according to claim 16, wherein:
cutting the grooves includes creating recast material at the seam, and depositing the sealing material into the grooves includes covering the recast material.

18. The method for fabricating the image sensors according to claim 16, wherein depositing the sealing material into the grooves further includes:
depositing a layer of the sealing material on the top surface of the image-sensor wafer.

19. The method for fabricating the image sensors according to claim 18, further comprising:
etching the layer to create a glass support on the top surface; and
bonding a glass window to the glass support.

20. The method for fabricating the image sensors according to claim 16, wherein:
cutting the grooves includes using a laser; and
sawing through the sealing material and the integrated-circuit wafer in the grooves includes using a wafer saw.
